(19) United States
(12) Patent Application Publication
(10) Pub. No.: US 2011/0297219 A1
(43) Pub. Date: Dec. 8, 2011

(54) METHOD AND MATERIALS FOR THE FABRICATION OF CURRENT COLLECTING STRUCTURES FOR PHOTOVOLTAIC DEVICES

(75) Inventors: Craig Vogeli, North Branch, MI (US); Carole DiDia, East China Township, MI (US); Mihaela Lucia Glavan, Sterling Heights, MI (US); Kesho Leach, Rochester, MI (US)

(73) Assignee: United Solar Ovonic LLC, Auburn Hills, MI (US)

(21) Appl. No.: 12/793,764

(22) Filed: Jun. 4, 2010

(51) Int. Cl. H01L 31/02; B32B 37/12

(52) U.S. Cl. 136/256; 156/297

(57) ABSTRACT

A bus grid structure is affixed to a photovoltaic device utilizing a double-sided adhesive tape in which one of the adhesive layers is electrically conductive and the other is electrically resistive. The tape is affixed to a photovoltaic device via the electrically resistive adhesive. Grid wires are applied to a top electrode of the photovoltaic device, and portions of those grid wires are adhered to the electrically conductive adhesive. A bus bar is also adhered to the electrically conductive adhesive so as to contact the portions of the grid wire. The assembly is laminated so as to bond the grid wires to the photovoltaic device and to the bus bar. Further disclosed are devices fabricated according to this method as well as electrically conductive double adhesive tapes utilized in the process.

### FIELD OF THE INVENTION

In general, this invention relates to photovoltaic devices. More specifically, the invention relates to methods and materials for affixing current collecting structures such as grid wires and bus bars onto photovoltaic devices.

### BACKGROUND OF THE INVENTION

Photovoltaic devices, even those of modest surface areas, require the use auxiliary current collecting structures to provide for the efficient collection of photo-generated current therefrom. These current collecting structures comprise electrically conductive elements such as grid wires, bus bars, and the like configured and arranged so as to provide a low resistivity, current carrying path between the photovoltaically active portions of the device and terminals, connectors, leads, or other such members. In some specific applications, the current collecting structures are comprised of a plurality of grid members disposed in electrical contact with an electrode of the photovoltaic device. These grid wires are also in electrical contact with a bus bar member and feed collected current thereto. This bus bar member may then be in electrical communication with another bus bar, a device terminal, a connector, or the like.

There are a number of different configurations of bus grid structures known in the prior art, and some examples thereof are found in pending U.S. patent application Ser. No. 12/207,014 filed Sep. 9, 2008, and entitled “Monolithic Photovoltaic Module” and in U.S. patent application Ser. No. 12/131,963 filed Jun. 3, 2008, and entitled “Method for Fabrication of Semiconductor Devices on Lightweight Substrates”. The disclosures of both of these patent applications are incorporated herein by reference.

In particular processes for the high-volume fabrication of photovoltaic devices, grid members are typically formed from a material which has a heat bondable, electrically conductive coating thereupon. These grid members are affixed to the electrode of the photovoltaic device and to bus bar structures by a laminating process involving heat and pressure. In any photovoltaic system, it is important that the junctions between the various components of the current collecting bus/grid structure have good electrical conductivity, so as to minimize the series resistivity of the device and maximize its photovoltaic efficiency.

As will be described hereinbelow, the present invention provides for an improvement in prior art processes for the fabrication of photovoltaic devices insofar as it provides a process by which the electrical conductivity of current-collecting bus-grid structures may be significantly improved. Furthermore, the process of the present invention is readily adaptable to currently employed high volume, automated fabrication processes. These and other advantages of the invention will be apparent from the drawings, discussion, and description which follow.

### BRIEF DESCRIPTION OF THE INVENTION

Disclosed is a method for affixing components of a bus grid structure onto a photovoltaic device. According to the method, one or more current-collecting grid wires are affixed to the top electrode of a photovoltaic device. A bus bar tape comprising a web of an electrically insulating material having an electrically conductive, pressure-sensitive adhesive on a first face thereof and a layer of an electrically resistive, pressure-sensitive adhesive disposed on an opposed second face thereof is affixed to the photovoltaic device by adhering the electrically resistive adhesive thereto. The bus bar tape thus defines a bus grid connection zone on the photovoltaic device. Portions of the grid wires are adhered to the bus bar tape by the electrically conductive, pressure-sensitive adhesive. Thereafter, an electrically conductive bus bar member is affixed to the bus bar tape via the electrically conductive adhesive so that the bus bar member is also in electrical contact with at least part of the portions of the grid wires adhered to the bus bar tape.

In some instances, the thus produced assembly is pressure laminated so as to strengthen the connection between the components. In specific instances, the electrically conductive, pressure-sensitive adhesive has an electrical resistance of no more than 0.04 ohms. In particular instances, the adhesive peel strength of the electrically conductive, pressure-sensitive adhesive is at least 40 ounces per inch of width.

In certain instances, the grid wires comprise a metallic wire, such as a copper wire, having an electrically conductive, bondable coating thereupon. The bondable coating may be a heat-activatable coating and may comprise a polymeric material having an electrically conductive material, such as carbon, dispersed therein.

The invention further comprises photovoltaic devices made according to the disclosed method.

### BRIEF DESCRIPTION OF THE DRAWINGS

FIG. 1 is a top plan view of a portion of a photovoltaic device illustrating a particular configuration of a bus grid structure;

FIG. 2 is a cross-sectional view of the device of FIG. 1 taken along line 2-2;

FIG. 3 is a cross-sectional view of the device of FIG. 2 following the implementation of a laminating step; and

FIG. 4 is an enlarged sectional view of a portion of the device of FIG. 3.

### DETAILED DESCRIPTION OF THE INVENTION

The present invention is directed to methods and materials whereby high conductivity connections may be established between components of a bus grid system which is affixed to a photovoltaic device. The present invention may be implemented in conjunction with variously configured photovoltaic devices and bus grid structures. For purposes of illustration it will be described with reference to one specific configuration of photovoltaic device, and it is to be understood that this invention may be otherwise implemented.

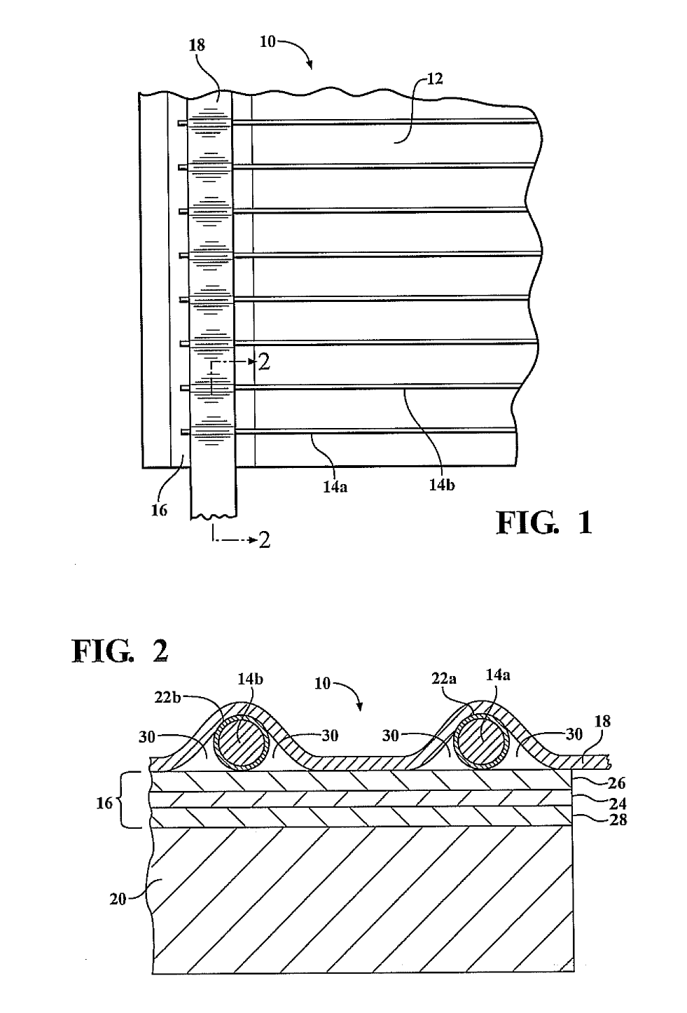

Referring now to FIG. 1, there is shown a top plan view of a portion of a photovoltaic device 10. The device 10 includes a body of photovoltaic material which, as is known in the art, will include at least a bottom electrode typically comprised of a metallic material. The bottom electrode may also comprise the substrate of the photovoltaic device, or it may be a separate element. The device will include a photovoltaic body comprised of a number of semiconductor layers and operative to absorb incident photons and generate a photovoltaic current in response thereto. This photovoltaic body is in electrical communication with the bottom electrode as well as with a top electrode 12, which is fabricated from an optically transparent, electrically conductive material such as a metal oxide material. The material of the top electrode 12 generally has a modest electrical conductivity; hence, the device 10 includes a plurality of current collecting grid wires, for example grid wires 14a, 14b affixed to the top electrode 12. In the context of this disclosure, these elements 14a, 14b are referred to as “grid wires”; however, it is to be understood that they may be configured as tapes, strips, or other such structures, all of which are included within the broad definition of “grid wires”. In one specific embodiment of the present invention, the grid wires 14a, 14b are fabricated from relatively thin, silver plated copper wires, and they have an outer coating of an electrically conductive thermoplastic material thereupon. This coating material may comprise a carbon loaded polymer. In the fabrication of the photovoltaic device 10, the grid wires 14a, 14b are laminated to the top electrode 12 by a combination of heat and pressure which thermally bonds the conductive coating to the electrode 12. Bonding conditions will depend upon the specific nature of the conductive thermoplastic coating; however, bonding typically involves applying a pressure of at least 13 psig at a temperature of at least 200° C. for a time of at least 45 seconds.

As will be further seen from FIG. 1, the device 10 includes a strip of a bus bar tape 16 affixed thereto. This bus bar tape defines a grid connection zone in which further connections are established. The bus bar tape 16 comprises a double-sided adhesive tape. As will be explained hereinbelow, the present invention recognizes that the nature of this tape is very critical to the establishment of high quality, low resistivity electrical connections in the bus grid structure, a fact which was not recognized or appreciated by the prior art.

The grid connection zone established by the tape 16 is electrically isolated from both the bottom electrode and the top electrode of the device 10. In this regard, the bus bar tape 16 may be applied directly atop the surface of the top electrode 12; or, in other embodiments, it may be applied to an exposed surface of the bottom electrode, to the substrate, or to some other portion of the photovoltaic device.

As will be seen from FIG. 1, portions of the grid wires 14a, 14b extend from the surface of the top electrode 12 onto the bus bar tape 16. The photovoltaic device 10 further includes a bus bar member 18 which is disposed in the grid connection zone defined by the bus bar tape 16. The bus bar member 18 is fabricated from an electrically conductive material such as a silver plated copper tape. As is shown in FIG. 1, the bus bar member 18 is adhered to the tape 16 by its top adhesive layer, and it contacts the portions of the grid wires 14a, 14b in the connection zone.

In FIG. 1, the bus grid system of the photovoltaic device 10 is defined by the grid wires 14 and bus bar member 18. In the operation of the device, the grid wires 14 collect photo-generated current and carry it to the bus bar member 18 which in turn carries that current to some further collection point such as a terminal, lead line, or other structure (not shown).

Referring now to FIG. 2, there is shown a cross-sectional view of the device 10 of FIG. 1 taken along line 2-2. In FIG. 2, the reference numeral 20 indicates a portion of the connection zone of the device 10; and in that regard, FIG. 2 illustrates a cross-sectional view of the bus bar tape 16, bus bar 18, and grid wires 14a, 14b. As mentioned above, the bus bar tape 16 may be disposed upon a portion of the top electrode of the photovoltaic device, upon a portion of the substrate, or upon some other part of the photovoltaic device. In this regard, it is to be understood that the segment of the device indicated by reference numeral 20 may include semiconductor layers and electrode structures, or it may merely comprise the substrate of the photovoltaic device; and the principles of the present invention are applicable to any such embodiments.

As shown in FIG. 2, the grid wires 14a, 14b each comprise a metallic core having an electrically conductive, thermoplastic coating 22a, 22b disposed thereupon. As will be seen from FIG. 2, the bus bar member 18 is in electrical contact with the grid wires 14a, 14b via the coating 22.

As will be further seen from FIG. 2, the bus bar tape 16 comprises a double-sided adhesive tape which includes an electrically insulating base material 24 having a layer of a first, adhesive material 26 affixed to a first face thereof and a layer of a second adhesive material 28 affixed to a second layer thereof. The tape 16 serves to adhere the grid wires 14 and bus bar member 18 to the subjacent portion 20 of the photovoltaic device while electrically isolating those elements 14 and 18 therefrom.

FIG. 2 shows the device in an initial stage of fabrication prior to lamination of the components of the bus grid structure to the device 10. As such, the grid wires 14 and bus bar member 18 are adhesively adhered to the device 10 by the tape 16 but have not been thermally bonded. In that regard, it will be noted that open spaces 30 exist proximate the grid wires 14, bus bar member 18, and upper layer 26 of the tape 16.

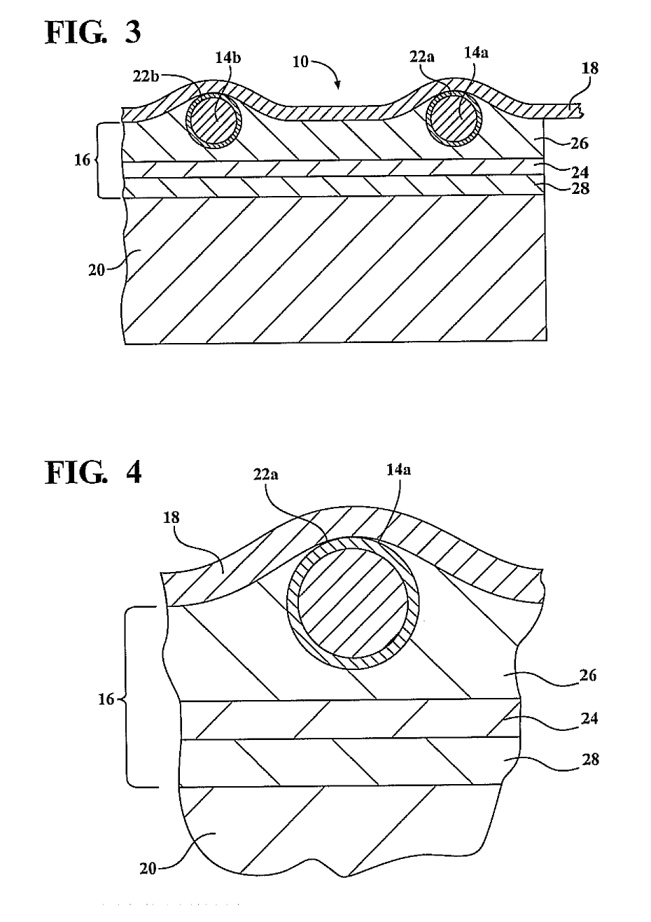

FIG. 3 shows the device 10 of FIG. 2 following a thermal lamination step. FIG. 4 is an enlarged fragmentary view of the FIG. 3 device specifically showing the region thereof in which the bus grid member 18 is thermally laminated to the first grid wire 14a. As mentioned above, the thermal lamination process involves the application of pressure and heat and serves to bond the grid wires to the upper electrode surface of the photovoltaic device as well as to the bus bar member 18. As will be seen in FIGS. 3 and 4, the lamination process compresses the grid wires 14 into the top adhesive layer 26 of the bus bar tape 16, and this causes the adhesive material 26 to at least partially fill the spaces 30 shown in FIG. 2 between the grid wires 14, tape 16, and bus bar member.

It is a significant finding of the present invention that this filling of the space by the top adhesive layer 26 has a very significant impact on overall photovoltaic device performance insofar as the filling directly influences the nature of the electrical connection between the bus bar member 18 and grid wire 14. As will be seen from FIG. 4, intrusion of the adhesive material 26 can actually decrease contact area between the grid wire 14 and bus bar member 18. This is significant since, in prior art techniques, both the upper layer of adhesive 26 and the lower layer of adhesive 28 of the tape 16 were fabricated from electrically resistive materials since conventional wisdom held that good electrical isolation must be maintained between the top electrode and bottom electrode of the photovoltaic device. The present invention has identified this intrusion of the adhesive as being an important factor in overall device efficiency and has departed from conventional wisdom and teaching and found that use of an electrically conductive adhesive for the top adhesive layer 26 will significantly improve overall photovoltaic device efficiency.

Thus, in accord with the present invention, bus grid structures are fabricated and deployed utilizing a bus bar tape which is comprised of a web of an electrically insulating material 24 having opposed first and second faces wherein a layer of an electrically conductive, pressure-sensitive adhesive 26 is disposed upon the first face of the insulating material 24 and a layer of an electrically resistive, pressure-sensitive adhesive 28 is disposed on the second face of the material 24. In this manner, the resistive losses occasioned by the nature of the junction between the grid wires 14 and bus bar member 18 are greatly diminished.

In accord with the present invention double-sided adhesive (DA) bus bar tape in which one of the adhesive layers is electrically conductive is advantageously employed for affixing bus grid structures to photovoltaic devices, and in particular for affixing grid wires to bus bar members through a thermal lamination process. Tape utilized in the present invention should include an electrically conductive adhesive having an electrical resistivity of no more than 10 ohms per square inch, and in particular instances a resistivity of no more than 5 ohms per square inch, and in particular instances a resistivity of no more than 2 ohms per square inch. The conductive adhesive should also have a high peel strength, and in particular instances this peel strength is at least 10 ounces per inch of width as measured by standard techniques. In specific instances, the peel strength is at least 20 ounces per inch of width, and in certain instances at least 40 ounces per inch of width.

A series of experiments were carried out evaluating and demonstrating the principles and advantages of the present invention. In these experimental series, photovoltaic devices were manufactured utilizing conventional double-sided adhesive tape incorporating two electrically resistive adhesive layers. This tape is commercially available from Toyo Inc. under the designation LEW 410. A series of like devices were fabricated in accord with the present invention utilizing a double adhesive tape having an electrically conductive layer (CDA tape). The tape utilized in this series of evaluations was generally equivalent to the commercial tape, except that the adhesive layer was electrically conductive. In that regard, the adhesive layer comprised a pressure sensitive adhesive having anisotropic, electrically conductive particles disposed therein. The tape had an electrical resistance of less than 0.02 ohm/square centimeter, and a thickness or up to 2 mils. Performance characteristics of devices manufactured in accord with the prior art and corresponding devices manufactured in accord with the present invention were evaluated with regard to performance characteristics including, among others, maximum power output (Pmax) and resistivity of the bus grid system (Rbb). In a first series of evaluations, a typical in line production process utilizing lamination conditions of 230° C. for 45 seconds at a pressure of approximately 42 kPa was employed. This set of operating parameters is typical of that used with an in line continuous fabrication process. Data is summarized in Table 1 below.

TABLE 1
In-line press: 230 C., 45 sec, −42 kPa. Standard cell construction

| CELL BARCODE | | Rbb | Pmax | Isc | Voc | | Imp | Vmp | Rs | Rsh | η |
|---|---|---|---|---|---|---|---|---|---|---|---|
| Cal#0.526 | DA Manufacturer | [mΩ] | [W] | [A] | [V] | FF | [A] | [V] | [mΩ] | [Ω] | [%] |
| 14024659 | Toyo ink DA Tape | 55.8 | 7.420 | 5.425 | 2.217 | 0.616 | 4.425 | 1.677 | 68.7 | 2.7 | 9.20 |
| 14024660 | CDA EXP2625- | 40.3 | 7.444 | 5.587 | 2.212 | 0.624 | 4.416 | 1.686 | 68.0 | 3.1 | 9.23 |
| | 10-F2 Tape | | | | | | | | | | |
| 14024661 | Toyo ink DA Tape | 57.4 | 7.158 | 5.445 | 2.203 | 0.596 | 4.318 | 1.658 | 71.6 | 2.3 | 8.88 |
| 14024662 | CDA EXP2625- | 42.6 | 7.272 | 5.428 | 2.206 | 0.607 | 4.366 | 1.666 | 69.5 | 2.7 | 9.02 |
| | 10-F2 Tape | | | | | | | | | | |
| 14024663 | Toyo ink DA Tape | 50.1 | 7.344 | 5.449 | 2.209 | 0.610 | 4.361 | 1.684 | 66.4 | 2.6 | 9.11 |
| 14024664 | CDA EXP2625- | 41.3 | 7.479 | 5.452 | 2.212 | 0.622 | 4.449 | 1.681 | 64.4 | 2.8 | 9.27 |
| | 10-F2 Tape | | | | | | | | | | |

| | | | | | | | | | | |
|---|---|---|---|---|---|---|---|---|---|---|
| avg. Toyo ink DA Tape | 54.4 | 7.507 | 5.440 | 2.210 | 0.608 | 4.368 | 1.673 | 68.9 | 2.5 | 9.06 |
| avg. CDA EXP2625-10-F2 Tape | 41.4 | 7.598 | 5.416 | 2.210 | 0.618 | 4.410 | 1.678 | 67.3 | 2.9 | 9.17 |
| avg. CDA EXP2625-10-F2/ | −23.9% | 1.2% | −0.4% | 0.0% | 1.7% | 1.0% | 0.3% | −2.3% | 13.4% | 1.2% |
| avg. Toyo DA% | | | | | | | | | | |

As will be seen, utilizing an electrically conductive double adhesive tape in accord with the present invention resulted in an overall reduction of 23.9% in bus grid system resistivity and an overall improvement of 1.2% in device efficiency and maximum power output.

A similar evaluation was carried out utilizing a lamination temperature of 210° C. at a time of 45 seconds and a pressure of approximately 13 psig. These operating conditions are typical of a commercially employed off line grid wire press apparatus used in production facilities. Data from this evaluation is summarized in Table 2 below.

TABLE 2
Off Line press: T = 210 C., 45 sec, −13 psig. Standard cell construction

| CELL BARCODE | | Rbb | Pmax | Isc | Voc | | Imp | Vmp | Rs | Rsh | η |
|---|---|---|---|---|---|---|---|---|---|---|---|
| Cal#0.526 | DA Manufacturer | [mΩ] | [W] | [A] | [V] | FF | [A] | [V] | [mΩ] | [Ω] | [%] |
| 14024718 | CDA EXP2625- | 32.0 | 7.728 | 5.357 | 2.225 | 0.649 | 4.469 | 1.729 | 61.5 | 3.6 | 9.58 |
| | 10-F2 Tape | | | | | | | | | | |
| 14024719 | Toyo inK DA Tape | 45.9 | 7.139 | 5.427 | 2.196 | 0.600 | 4.314 | 1.654 | 63.3 | 2.3 | 8.85 |
| 14024720 | CDA EXP2625- | 34.8 | 7.350 | 5.416 | 2.208 | 0.615 | 4.359 | 1.686 | 65.8 | 2.4 | 9.11 |
| | 10-F2-Tape | | | | | | | | | | |
| 14024721 | Toyo inK DA Tape | 44.5 | 7.257 | 5.454 | 2.199 | 0.605 | 4.350 | 1.676 | 64.1 | 2.3 | 9.00 |

| | | | | | | | | | | |
|---|---|---|---|---|---|---|---|---|---|---|
| avg. Toyo ink DA Tape | 45.2 | 7.198 | 5.440 | 2.198 | 0.602 | 4.322 | 1.665 | 63.7 | 2.3 | 8.92 |
| avg. CDA EXP2625-10-F2 Tape | 35.4 | 7.539 | 5.386 | 2.217 | 0.652 | 4.414 | 1.707 | 63.7 | 3.0 | 9.35 |
| avg. CDA EXP2625-10-F2/ | −26.1% | 4.7% | −1.0% | 0.9% | 4.9% | 2.1% | 2.5% | −0.1% | 31.0% | 4.7% |
| avg. Toyo ink % | | | | | | | | | | |

As will be seen, electrical resistivity of the bus grid system was reduced by 26.1%, and maximum power output and device efficiency were correspondingly increased by 4.7% through the use of the present invention. The foregoing demonstrates that the present invention recognizes and addresses a heretofore unknown source of resistance losses in photovoltaic devices and provides heretofore unappreciated and unanticipated benefits. The methods and materials of the present invention may be readily implemented into conventional production processes without any major modifications to equipment or techniques.

The present invention has been described with reference to particularly configured photovoltaic devices; however, it will be apparent to one of skill in the art from the foregoing drawings, discussion, and description that this invention may be implemented in connection with a variety of otherwise configured photovoltaic devices and manufacturing processes. The foregoing is illustrative of specific embodiments of the invention but is not meant to be a limitation upon the practice thereof. It is the following claims, including all equivalents, which define the scope of the invention.

1. A method for affixing a bus grid structure to a photovoltaic device, said method comprising:
providing a photovoltaic device having a top, electrically conductive electrode;
affixing at least one current collecting grid wire to said top electrode;
providing a bus bar tape comprising a web of an electrically insulating material having opposed first and second faces wherein a layer of an electrically conductive, pressure-sensitive adhesive is disposed upon said first face, and a layer of an electrically resistive, pressure-sensitive adhesive is disposed on said second face;
affixing said bus bar tape to said photovoltaic device by adhering said layer of an electrically resistive, pressure-sensitive adhesive thereto; whereby said bus bar tape defines a bus grid connection zone on said photovoltaic device;
affixing a portion of said at least one grid wire to said bus bar tape by adhering said portion to said layer of an electrically conductive, pressure-sensitive adhesive;
providing an electrically conductive bus bar member; and
affixing said bus bar member to said bus bar tape so that said bus bar member is in electrical contact with at least some of said portion of said at least one grid wire, and so that said bus grid member is adhered to said layer of an electrically conductive, pressure-sensitive adhesive.

2. The method of claim 1, wherein said electrically conductive, pressure-sensitive adhesive has an electrical resistance of no more than 0.04 ohms.

3. The method of claim 1, wherein said electrically conductive, pressure-sensitive adhesive has a peel strength of at least 40 ounces per inch of width.

4. The method of claim 1, wherein said web of an electrically insulating material of said bus bar tape comprises a polyester polymer.

5. The method of claim 1, wherein said electrically resistive adhesive has an electrical resistance of less than 0.02 ohms per square centimeter.

6. The method of claim 1, wherein said grid wire comprises a metallic wire having an electrically conductive, bondable coating thereupon.

7. The method of claim 6, wherein said bondable coating is a heat-activatable coating and wherein the step of affixing said bus bar member to said bus bar tape includes the further step of activating said bondable coating so as to bond said grid wire to said bus bar member.

8. The method of claim 7, wherein said step of activating said bondable coating comprises applying pressure and heat to said bus bar member and said coating.

9. The method of claim 8, wherein the step of activating said bondable coating comprises applying a pressure of at least 13 psig to said bus bar member and said coating at a temperature of at least 200° C. for a time of at least 45 seconds.

10. The method of claim 6, wherein said metallic wire is a copper wire and said bondable coating comprises a thermoplastic polymer having carbon dispersed therein.

11. The method of claim 10, wherein said copper wire is coated with silver.

12. The method of claim 1, wherein said bus bar member comprises a copper tape.

13. The method of claim 12, wherein said copper tape includes a silver coating on at least a portion of the surface thereof.

14. A photovoltaic device comprising:
a top, electrically conductive electrode;
a bus bar tape comprising a web of an electrically insulating material having opposed first and second faces and further including a layer of an electrically conductive, pressure-sensitive adhesive disposed upon said first face and a layer of an electrically resistive, pressure-sensitive adhesive disposed on said second face, said bus bar tape being affixed to said photovoltaic device so that said layer of an electrically resistive, pressure-sensitive adhesive is bonded to said photovoltaic device so as to define a bus grid connection zone upon said photovoltaic device;
at least one grid wire having a first portion thereof affixed to said top electrode in electrical communication therewith, and a second portion being adhered to said bus bar tape by said layer of an electrically conductive, pressure-sensitive adhesive; and
an electrically conductive bus bar member which is affixed to said bus bar tape so that it is in electrical contact with at least some of said second portion of said at least one grid wire and so that it is adhered to said layer of an electrically conductive, pressure-sensitive adhesive.
